(19) United States
(12) Patent Application Publication
(10) Pub. No.: US 2005/0180102 A1
(43) Pub. Date: Aug. 18, 2005

(54) Cooling system for electric element of personal computer

(76) Inventor: Hwee Chul Kim, Anyang-si (KR)

Correspondence Address: BAKER & BOTTS, 30 ROCKEFELLER PLAZA, NEW YORK, NY, 10112, US

(21) Appl. No.: 10/507,294

(22) PCT Filed: Mar. 11, 2003
(86) PCT No.: PCT/KR03/00472

(30) Foreign Application Priority Data
Mar. 11, 2002 (KR) 20-2002-0007072

(51) Int. Cl. H05K 7/20

(52) U.S. Cl. 361/694; 361/687

(57) ABSTRACT

The present invention relates to an effective cooling system for an electric element of a personal computer. The present invention provides the cooling system for the inhaling unit for inhaling air from outside by being positioned at a rear portion of a PC case; an air duct of which one end is connected to the inhaling unit and another end is connected to the electric element to be cooled so as to provide the flow path of the air enforced to be inhaled from outside by using the inhaling unit; and connecting unit for establishing a reciprocal connection between the inhaling unit and the air duct.

### TECHNICAL FIELD

The present invention relates to a cooling system for electric elements in a personal computer PC; and, more particularly, to a cooling system for cooling electric element in PC by directly leading to inhale external air to a central processor unit and exhaling internal air to outside during preventing to re-inhale exhaled internal air into PC.

### BACKGROUND ARTS

Generally, there are many electric elements equipped in a personal computer PC such as a central processing unit CPU, an external memory device, a memory, a graphic card and a sound card. The electric elements in PC are operated by electric power and also generate a heat. As a result, inside temperature of PC is increased. The Heat generated by the electric elements is one of factor lowering a performance and reducing life time of the PC, therefore, internal temperature of PC has to be controlled by cooling down the heat generated by electric elements. Specially, the central processing unit CPU generates most of heat generated by electric elements and its performance is easily degraded by high temperature of inside PC. The performance of CPU may depend on how to cool down the internal temperature or how to control heat generated by the CPU. Therefore, the PC usually equips an exhale fan installed at a back side of a case of PC for exhaling internal warm air to outside and inhaling external cool air through small holes on front or lateral side of the case of PC to generate air ventilation. By exhaling warm inside air to outside and inhaling cool external air to inside of PC, the air of inside PC is ventilated from the inside to outside. The ventilation of air can cool down the electric elements of PC, which generate the heat to increase temperature of inside of PC. Specially, a cooling fan is directly installed on a specific electric element, which generates most of heat such as CPU for controlling inside temperature of the PC. The cooling system is very important since the performance and life time of PC may be decreased by internal temperature of the PC.

Hereinafter, a conventional cooling system for cooling internal temperature of PC is explained as referring to FIGS. 1A and 1B.

One of embodiments of the conventional cooling system is installed in the PC having a data input/output device such as a floppy drive, a hard disk and a CD Rom installed on a front side of PC, a mainboard installed center of PC by connecting to back side of PC, wherein the mainboard includes a CPU 3, a memory 5 and a plurality of expansion devices 2 and a power supplier 4 is installed on upper side of back of PC. The above mentioned electric elements generate heat and especially the CPU generates most of heat generated by the electric elements.

General cooling system of the PC includes an exhale fan 12 installed at the power supplier 4, a cooling fan for CPU and a plurality of air holes 6, 7 and 8 formed on a front and lateral side of a PC case.

As shown in FIG. 1B, an external cool air is inhaled through a plurality of air holes when the exhale fan 12 and cooling fan 11 are running. The inhaled cool air is getting warm by traveling through electric elements of the PC such as the data input/output device 1, an additional slot device 2 and a memory before cooling CPU by using the cooling fan 11. Therefore, cooling efficiency is degraded since the inhaled air is getting warmer and flows to the CPU.

As shown in FIGS. 2A and 2B, in other embodiment of the conventional cooling system for electric elements, the inhale fan 13 is installed at back side of a PC case for increasing cooling affection of CPU. By installing the inhale fan 13, a path of supplying external cool air to the CPU is shorten and as a result, comparatively lower temperature air is supplied to the CPU. However, as shown in FIG. 2b, a part of the internal warm air exhaled from the exhale fan 12 is inhaled again by the inhaled fan 13. As a result, an effectiveness of cooling is decreased.

### DISCLOSURE OF THE INVENTION

It is, therefore, an object of the present invention to provide a cooling system for electric elements in a personal computer PC by directly leading external cool air from an inhale fan to the CPU and preventing to re-inhale exhaled internal warm air through an inhale fan.

In accordance with an aspect of the present invention, there is provided a cooling system for electric elements in a personal computer PC, including: inhale unit being equipped at a back side of the PC case for inhaling an external cool air into the PC; a air duct having one end connected to the inhale unit and other end connected to a desired electric element for directly leading the external cool air to the desired electric element; and connection parts equipped both ends of the air duct for connecting the inhale unit and the air duct or connecting the air duct and the desired electric element.

Also, the cooling system further including: a plurality of holes formed on a front and lateral side of the PC case for inhaling the external cool air; and a exhale unit equipped on a back side of the PC case for exhaling an internal warm air to outside.

Furthermore, the cooling system further includes an exhale air leading pipe being connected to the exhale unit for leading the internal warm air from the exhale unit to upward of outside to the PC in order to prevent to re-inhale to inside of the PC.

Above mentioned exhale air leading pipe includes a connection plate on bottom of the exhale air leading pipe for connecting the exhale air leading pipe to the exhale unit; an open upper end for leading the internal warm air exhaled from the exhale unit to upward of outside of the PC; and a bended pipe being bended to upward for connecting the connection plate to the open upper end and leading the internal warm air from the exhale unit to the open upper end.

The above mentioned air duct has wrinkled surface.

Also, the air duct can be formed by using nonwavon fabric for being functioned as a soundproof function and a filter for filtering dust.

The air duct and connection unit are formed as one piece and a rotation unit can be interleaved between the air duct and connection unit. That is, the rotation unit prevents over tilting the air duct.

Also, the air duct and connection unit can be provided as independent parts and the air duct and connection unit are connected by coupling units, wherein the coupling unit can be a cable and a bond.

The connection units are connected to electric elements or exhale unit by using screws, snap rings or rivets.

Also, a plurality of flexible holding taps is equipped to one end of connection units for connecting the air duct to electric elements or exhale unit.

### BRIEF DESCRIPTION OF THE DRAWING(S)

The above and other objects and features of the present invention will become apparent from the following description of the preferred embodiments given in conjunction with the accompanying drawings, in which:

FIG. 1A is a view depicting conventional cooling system for electric elements in a personal computer PC;

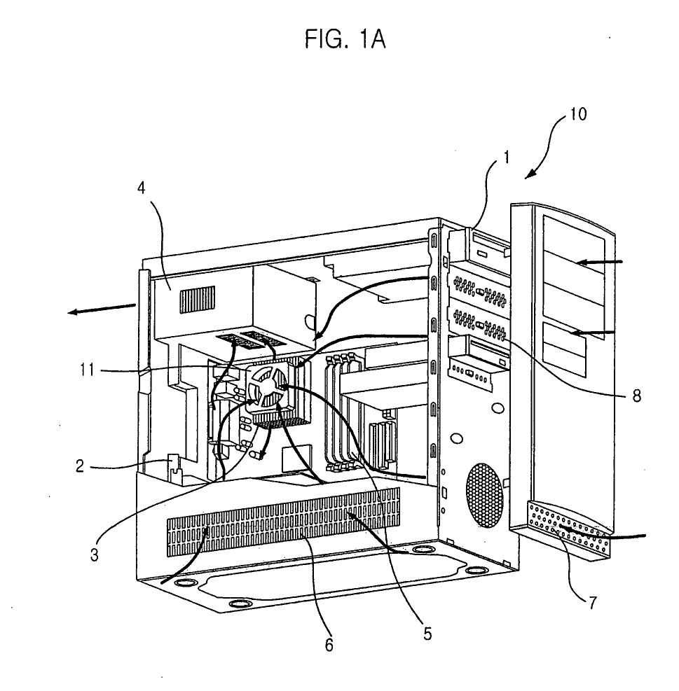

FIG. 1B is a side view of conventional cooling system in FIG. 1A showing paths of air ventilation;

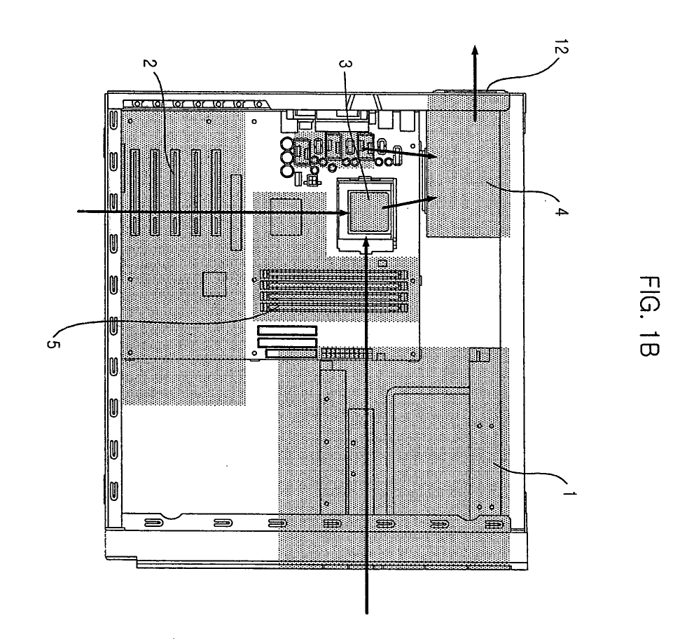

FIG. 2A is a view depicting another conventional cooling system for electric elements in a personal computer PC;

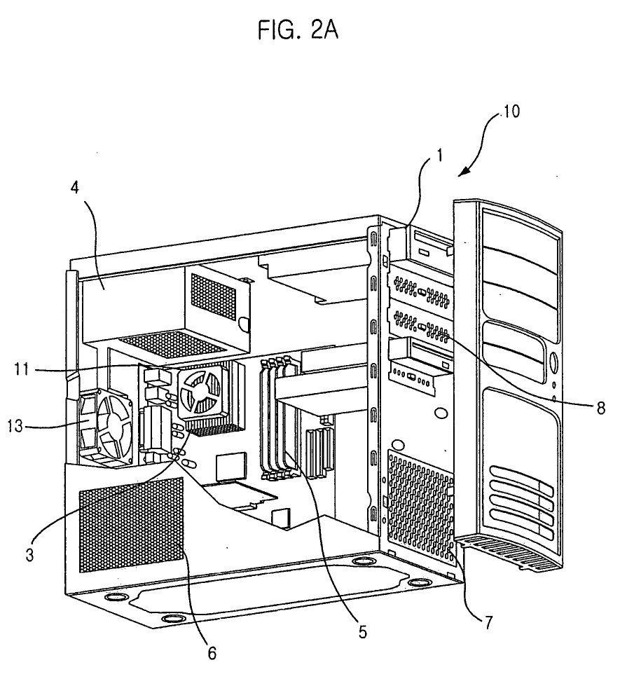

FIG. 2B is a side view of conventional cooling system in FIG. 2A showing paths of air ventilation;

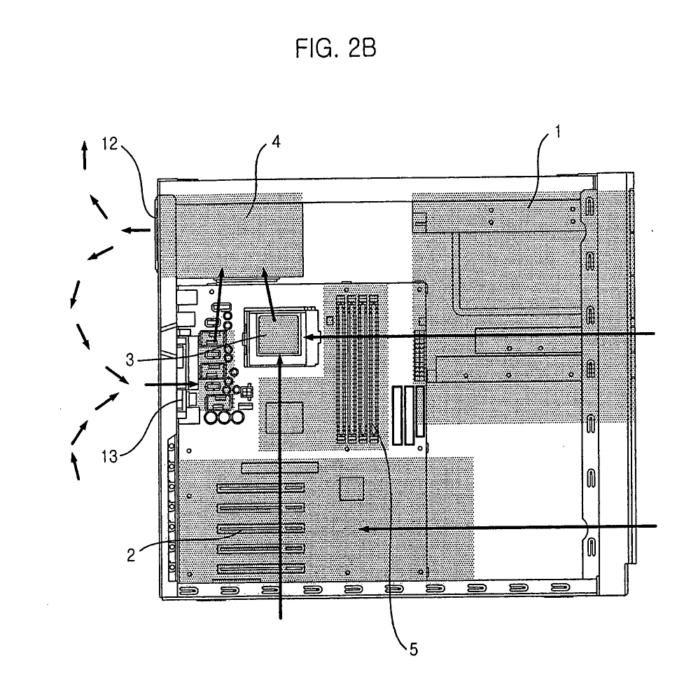

FIG. 3 is a view illustrating a configuration of a cooling system in accordance with a preferred embodiment of the present invention;

FIG. 4 is a view of a connection part of the cooling system in accordance with the present invention;

FIG. 5 is a view of another connection part of the cooling system in accordance with the present invention;

FIG. 6A is a view illustrating a cooling system installed in PC in accordance with a preferred embodiment of the present invention; and

FIG. 6B is a view showing paths of air ventilation generated by the cooling system of the present invention in FIG. 6A.

### BEST MODES FOR CARRYING OUT THE INVENTION

Other objects and aspects of the invention will become apparent from the following description of the embodiments with reference to the accompanying drawings, which is set forth hereinafter.

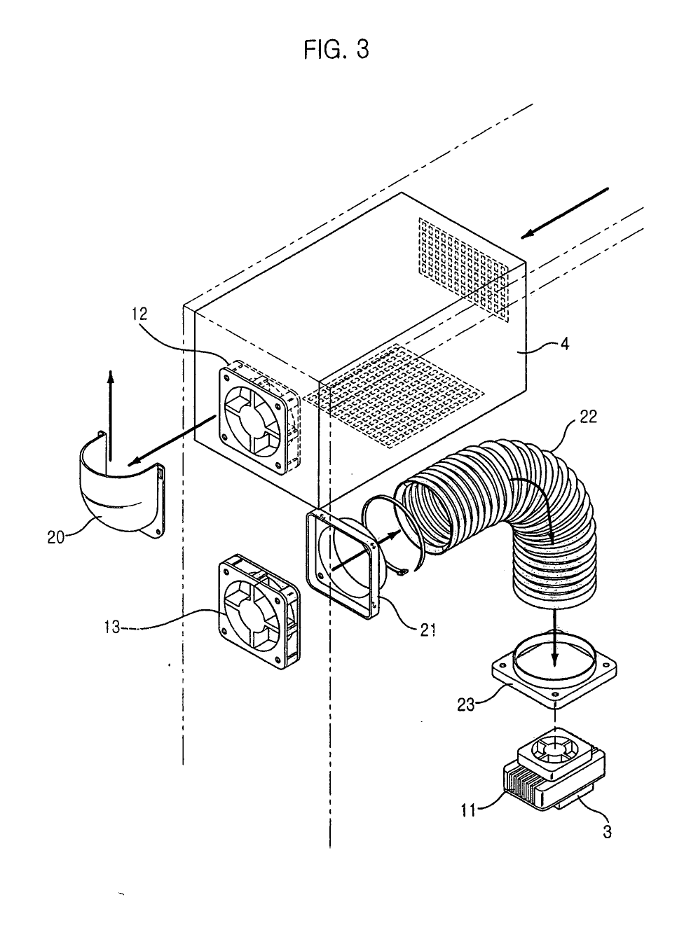

As referring to FIGS. 3 to 6B, a cooling system for electric elements in a personal computer PC is explained in below. In a preferred embodiment of the present invention explained in here, an electric element to be cooled is a CPU.

Referring to FIG. 3, the cooling system of the present invention includes an inhale fan 13 installed on a back side of a PC case, a air duct 22 for directly leading an external cool air to the CPU, a first connection part 21 for connecting the inhale fan 13 and the air duct 22, a second connection part 22 for connecting a cooling fan of the CPU and the air duct 22 and an exhale air leading pipe 20 being connected to the inhale fan 13 and having a form of a bended pipe with an open upper portion for effectively leading an exhaled internal air of PC from the exhale fan to upward of outside and with a flat bottom portion for connecting to the exhale fan 12. The exhale air leading pipe 20 leads the exhaled air from the exhale fan 12 to upward of outside to prevent re-inhaling the exhaled internal warm air to the inhale fan 13.

The air duct 22 provides a path of air ventilation from the CPU to the exhale fan and it is formed with wrinkled pipe in order to smoothly bend to any desired direction for providing a air path between the exhale fan to any electric element of PC.

A metal thin film, a polyvinyl chloride PVC and a synthetic resin material are used for the air duct 22 and also a non-waven fabric can be used too. By using the non-waven fabric for the air duct 22, the non-waven fabric can be functioned as a soundproofing material and a filter for filtering dust.

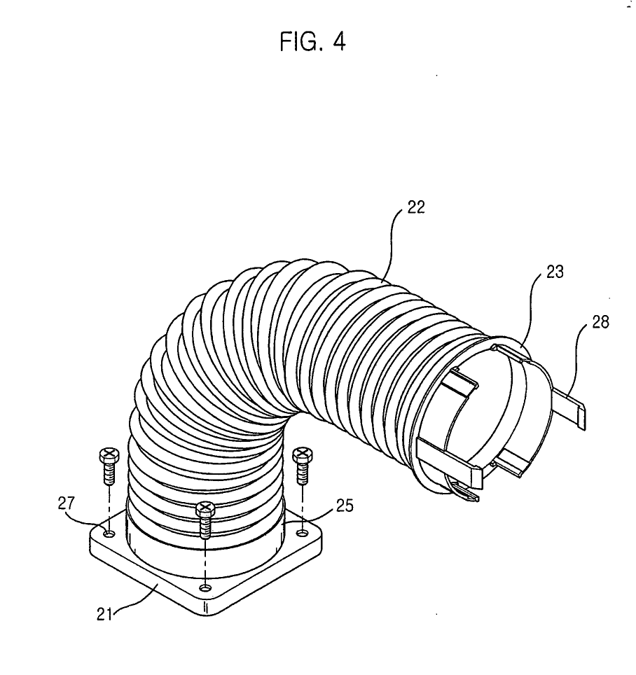

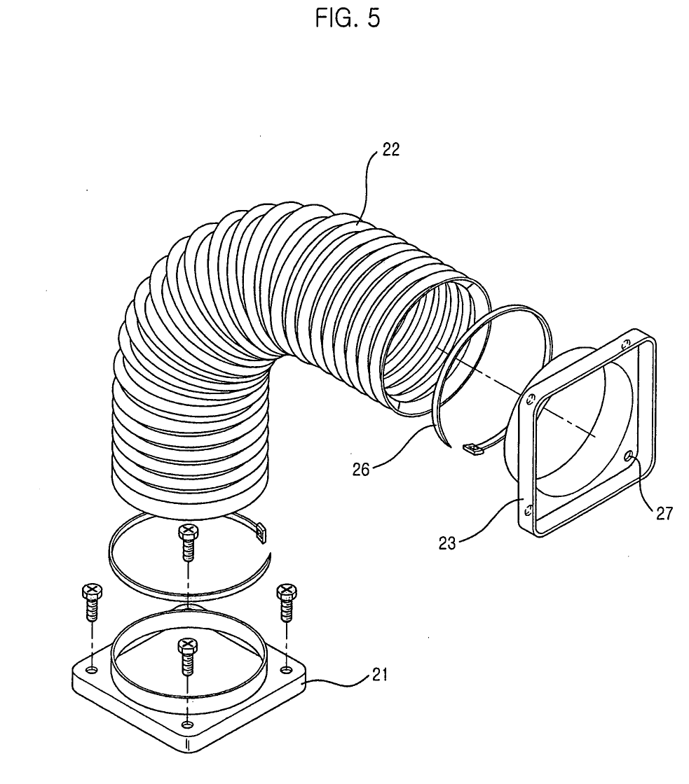

FIGS. 4 and 5 show examples of a cooling system with an air duct and connection parts in PC in accordance with a preferred embodiment of the present invention.

Referring to FIG. 4, the first connection part 21 is coupled to one end of the air duct 22 and the second connection part 23 is coupled to another end of the air duct 22. Between the air duct 22 and the first connection part 21, a rotation unit 25 interleaved with bearings may be equipped for preventing over tilting the air duct 22 when the second connection part 23 is fixed to a specific electric element and the first connection plate 21 is fixed to the exhale fan.

FIG. 5 shows another embodiment of the cooling system with the air duct and connection parts. It is also designed to prevent over tilting the air duct 22. It includes a connection unit 26 for connection the air duct 22 and each of the first and second connection parts 22 and 23. That is, the first connection part 21, the air duct 22 and the second connection part 23 are independently provided. The first connection plate 21 can be connected to the exhale fan independently and then the second connection part 23 is connected to a desired electric element independently. After connecting the first and second connection parts, the air duct 22 is connected to the first and second connection parts by tilting the air duct as much as it desires. Therefore, it prevents over tilting the air duct 22 comparing to the embodiment of the air duct 22 with the first and second connection parts in FIG. 4.

The connection unit 26 is manufactured with a cable for connecting the air duct to the connection parts by tying and tightening.

As shown in FIG. 5, a connection hole 27 is formed at the first and second connection parts for connecting the first and second connection parts to the exhale fan and a desired electric element by using a screw, a snap ring and a rivet. As shown in FIG. 4, a plurality of flexible holding taps 28 is equipped at second connection parts 23. That is, it is used for connecting the air duct 22 to a desired electric element such as the CPU.

Hereinafter, operation of the cooling system for electric element in PC in accordance with the present invention is explained in below.

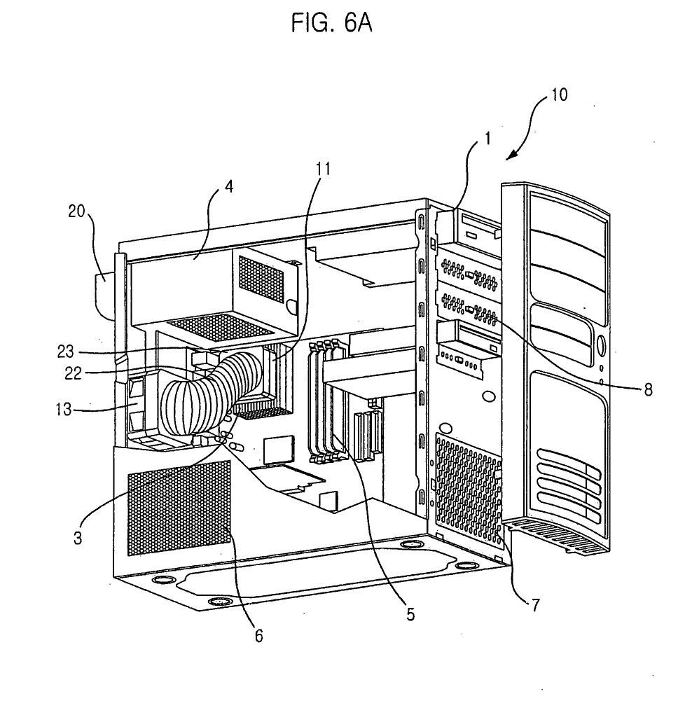

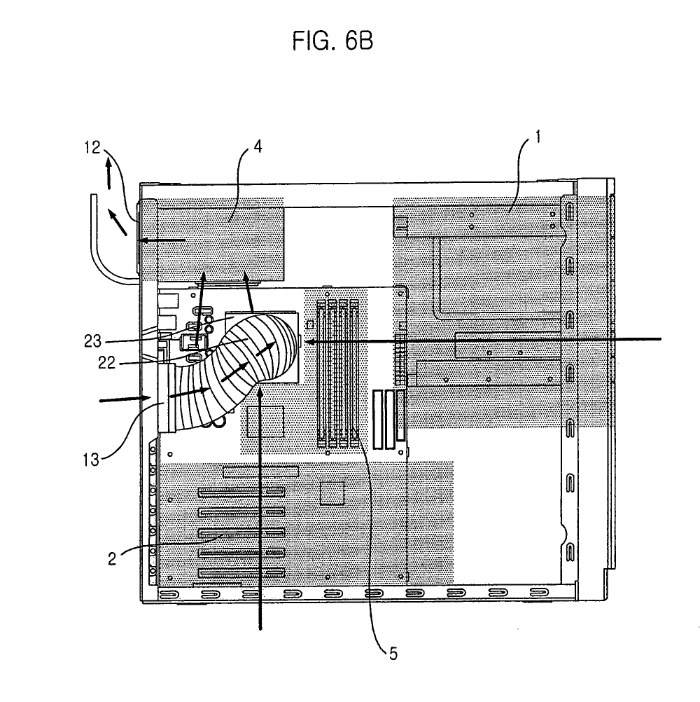

As shown in FIGS. 6A and 6B, the cooling system of the present invention inhales external cool air through a plurality of holes 6, 7 and 8 on a front and lateral side of a PC case and exhales internal warm air through the exhale fan 12 installed on a power supplier 4. Comparing to the convention system, external cool air inhaled by the inhale fan is lead directly to the CPU through the air duct 22 and as a result, air ventilation may be accelerated with cooling fan 11 on the CPU. Therefore, the CPU can be effectively cooled down.

Furthermore, the exhale air leading pipe 20 is installed by connecting to the exhale fan 12 on back side of the PC case and it prevents to re-inhale the exhaled warm internal air through the inhale fane 13, therefore, it increase cooling effectiveness of entire PC.

As shown in FIG. 6B, when the PC is operated, the exhale fan 12 runs to exhale internal warm air of the PC to outside and it causes to inhale external cool air through a plurality of holes 6, 7, and 8 on a front and lateral side of the PC case. The inhaled external cool air is ventilated in inside of PC in order to cool down electric elements, which generate heat to increase internal temperature of PC. After cooling down the electric elements, the inhaled external cool air becomes to internal warm air and the internal warm air is exhaled by the exhale fan 12 to the outside. When exhaling the internal warm air, the exhale air leading pipe 20 leads to exhale the internal warm air to upward of outside PC in order to prevent re-inhaling exhaled internal warm air into the PC through the inhale fan 13 equipped on bottom of the exhale fan 12. Furthermore, the external cool air is directly leaded to the CPU from the inhale fan 13 by the air duct 22. As a result, a cooling effectiveness of the CPU can be maximized. Therefore, the present invention can maximize the cooling effectiveness of the CPU, which mostly affects a performance of the PC, while maintaining same cooling effectiveness of other electric elements comparing to the conventional cooling system.

In this specification, the CPU is used as an example for reducing heat by directly leading external cool air by using the air duct 22, however, the cooling system of the present invention can be used for other electric elements such as a hard drive or chip set.

As mentioned above, the present invention can directly lowering internal temperature of the PC by directly leading an external cool air to the CUP, which generate most of heat to increase internal temperature of the PC. Therefore, the present invention can increase a performance of PC.

Also, the present invention can prevent to re-inhale the exhaled internal warm air in order to increase the cooling effectiveness of electric elements of PC. As a result, the PC can be stabilized by reducing internal temperature.

While the present invention has been described with respect to certain preferred embodiments, it will be apparent to those skilled in the art that various changes and modifications may be made without departing from the scope of the invention as defined in the following claims.

1. A cooling system for electric elements in a personal computer PC, comprising:
inhale mean being equipped at a back side of the PC case for inhaling an external cool air into the PC;
an air duct having one end connected to the inhale mean and other end connected to a desired electric element for directly leading the external cool air to the desired electric element; and
connection parts equipped both ends of the air duct for connecting the inhale means and the air duct or connecting the air duct and the desired electric element.

2. The cooling system as recited in claim 1 further comprising:
a plurality of holes formed on a front and lateral side of the PC case for inhaling the external cool air; and
exhale mean equipped on a back side of the PC case for exhaling an internal warm air to outside.

3. The cooling system as recited in claim 2, the exhale means and inhale means are an electric fan.

4. The cooling system as recited in claim 2, further comprising an exhale air leading pipe being connected to the exhale means for leading the internal warm air from the exhale means to upward of outside to the PC in order to prevent to re-inhale to inside of the PC.

5. The cooling system as recited in claim 4, the exhale air leading pipe includes:
a connection plate on bottom of the exhale air leading pipe for connecting the exhale air leading pipe to the exhale means;
an open upper end for leading the internal warm air exhaled from the exhale means to upward of outside of the PC; and
a bended pipe being bended to upward for connecting the connection plate to the open upper end and leading the internal warm air from the exhale means to the open upper end.

6. The cooling system as recited in claim 1, the air duct includes a air duct pipe having a form of wrinkled pipe and connection means at both ends of the air duct pipe.

7. The cooling system as recited in claim 6, the air duct pipe is produced by using a non-woven fabric.

8. The cooling system as recited in claim 1, the air duct further includes a rotation means interleaved between the connection means and the air duct.

9. The cooling system as recited in claim 8, the rotation means is produced by using a pan bearing.

10. The cooling system as recited in claim 1, the air duct is constructed by assembling independent parts of connection means and an air duct pipe.

11. The cooling system as recited in claim 10, wherein the connection means is a cable.

12. The cooling system as recited in claim 10, wherein the connection means is a sticking unit by bonding.

13. The cooling system as recited in claim 1, the connection part is fixed with a screw to electric elements or to the exhale means.

14. The cooling system as recited in claim 1, the connection part is fixed with a snap ring to electric elements or to the exhale means.

15. The cooling system as recited in claim 1, the connection part is fixed with a rivet to electric elements or to the exhale means.

16. The cooling system as recited in claim 1, the connection part has a plurality of flexible holding taps for connecting to electric element or to exhale means.
